(19) United States
(12) Patent Application Publication
(10) Pub. No.: US 2024/0395711 A1
(43) Pub. Date: Nov. 28, 2024

(54) SPLIT BACKSIDE POWER RAIL FOR ISOLATED SUPPLY

(71) Applicant: International Business Machines Corporation, Armonk, NY (US)

(72) Inventors: Brent A. Anderson, Jericho, VT (US); Albert M. Chu, Nashua, NH (US); Nicholas Anthony Lanzillo, Wynantskill, NY (US); Lawrence A. Clevenger, Saratoga Springs, NY (US); Ruilong Xie, Niskayuna, NY (US); Reinaldo Vega, Mahopac, NY (US)

(21) Appl. No.: 18/321,891

(22) Filed: May 23, 2023

(51) Int. Cl. H01L 23/528; H01L 21/768

(52) U.S. Cl. CPC H01L 23/5286; H01L 21/76895

(57) ABSTRACT

A semiconductor structure is presented including a plurality of backside supply rails, a primary rail, a first secondary rail and a second secondary rail, wherein the second secondary rail is isolated from the primary rail, and a transistor connecting the first secondary rail to the second secondary rail to supply power therebetween. The primary rail is contiguous only with the second secondary rail. A width of the first and second secondary rails is equal to a width of the primary rail. A supply voltage connection for the first and second secondary rails is provided by a via connected to the primary rail.

### BACKGROUND

The present invention relates generally to semiconductor devices, and more specifically, to constructing a split backside power rail for isolated supply.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a plurality of backside supply rails, a primary wide rail region, and a plurality of adjacent narrow rail regions, wherein at least one of the adjacent narrow rail regions is isolated from the primary wide rail region.

In accordance with another embodiment, a semiconductor structure is provided. The semiconductor structure includes a primary rail, a first secondary rail and a second secondary rail, wherein the second secondary rail is isolated from the primary rail, and a transistor connecting the first secondary rail to the second secondary rail to supply power therebetween.

In accordance with yet another embodiment, a method is provided. The method includes constructing a plurality of backside supply rails, constructing a primary wide rail region, and constructing a plurality of adjacent narrow rail regions, wherein at least one of the adjacent narrow rail regions is isolated from the primary wide rail region and wherein the primary rail is contiguous only with the second secondary rail.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure where device layers are formed over a first substrate, in accordance with an embodiment of the present invention;

FIG. 2 is a cross-sectional view of FIG. 1, where middle-of-line (MOL) and back-end-of-line (BEOL) layers are formed over the device layer, in accordance with an embodiment of the present invention;

FIG. 3 is a cross-sectional view of FIG. 2, where a second substrate is formed over the MOL and BEOL layers, in accordance with an embodiment of the present invention;

FIG. 4 is a cross-sectional view of FIG. 3, where the structure is flipped and the first substrate is selectively removed, in accordance with an embodiment of the present invention;

FIG. 5 is a cross-sectional view of FIG. 4, where vias are formed to the device layer, in accordance with an embodiment of the present invention;

FIG. 6 is a cross-sectional view of FIG. 5, where a backside power delivery level is formed over the vias, in accordance with an embodiment of the present invention;

FIG. 7 is a cross-sectional view of FIG. 6, where narrow rail cuts are formed, in accordance with an embodiment of the present invention;

FIG. 8 is a cross-sectional view of FIG. 7, where additional backside BEOL is formed over the narrow rail cuts, in accordance with an embodiment of the present invention;

FIG. 9 is a cross-sectional view of FIG. 6, where a via is connected to the primary rail region, in accordance with an embodiment of the present invention;

FIG. 10 is a top view of FIG. 8, where the wide rails and the narrow rails are illustrated, in accordance with an embodiment of the present invention; and

FIG. 11 is a top view of FIG. 8, where the wide rails and the narrow rails are illustrated, as well as an MOL contact connecting the narrow rails, and gating circuits used to supply power between the narrow rails, in accordance with an embodiment of the present invention.

Throughout the drawings, same or similar reference numerals represent the same or similar elements.

### DETAILED DESCRIPTION

Embodiments in accordance with the present invention provide methods and devices for constructing a split backside power rail for isolated supply. The power rail at a given level is split into multiple parallel power rails referred to as narrow rails. Gating circuits are also used to supply power between the narrow rails (or split rails).

Fin-based active devices, primarily transistors, are extensively applied for the production of standard cells and other active device configurations processed in the front-end-of-line (FEOL) part of the integrated circuit fabrication process, and include finFETs, as well as more recent devices based on nano-wires or nano-sheets. An example technology involves the use of buried interconnect rails in the FEOL. Buried power rails (BPRs) can directly connect the transistors in the FEOL to a power delivery network located entirely on the back side of an integrated circuit chip. In particular, the source or drain area of a number of transistors are directly connected to a buried rail. The current practice for realizing this configuration is to produce an interconnect via to the buried rail, and to couple the interconnect via to the source or drain area through a local interconnect that is part of the source/drain contact level of the chip, also referred to as the “middle end of line,” which is a transition between the active devices in the FEOL, and the interconnect levels (M1, M2, etc.,) in the back-end-of-line (BEOL).

Some implementations of this approach have a number of drawbacks. As the rails are buried underneath the active devices, the size of the buried power rail (BPR) is limited by the cell-to-cell space between two nearby active regions. As cell height scales down, so does the cell-to-cell space, the buried power rail size decreases, and its resistance increases, which can potentially degrade circuit performance.

Embodiments in accordance with the present invention can alleviate such spacing issues by providing a method and structure of forming a split backside power rail for isolated supply. The chip includes backside supply rails having a primary wide rail region and adjacent narrow rail regions with one of the narrow rail regions being isolated from the wide rail region. The wide rail region and one narrow rail region can be contiguous. The width of the two narrow rail regions is equal to a width of the wide rail region. The rails are located at N-N and/or P-P boundaries. In one embodiments, adjacent narrow rail regions are connected by a transistor to provide supply from one narrow rail region to the adjacent narrow rail region. In another embodiment, the adjacent narrow rail regions have a same voltage. In other embodiments, the supply voltage connection for the narrow rail region is provided by a via to connect to the wide rail region.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

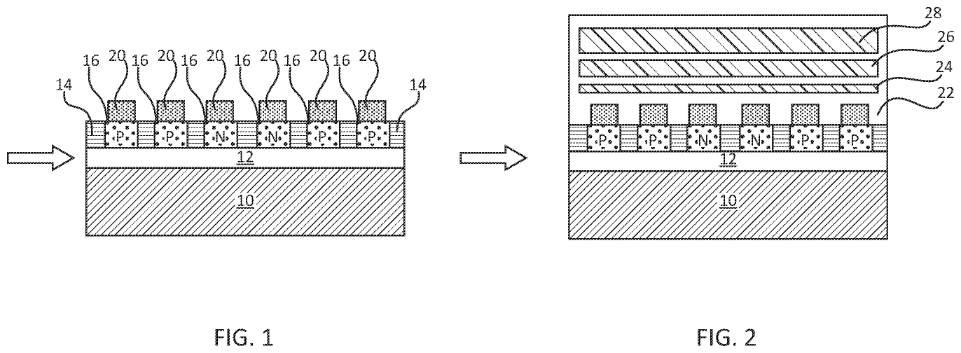

FIG. 1 is a cross-sectional view of a semiconductor structure where device layers are formed over a first substrate, in accordance with an embodiment of the present invention.

A dielectric layer 12 is formed over a substrate 10. A device layer is formed over the dielectric layer 12. The device layer includes p-type regions 16 and n-type regions 18. In one example, the n-type regions 18 are centrally located with respect to the p-type regions 16. The p-type regions 16 and the n-type regions 18 are separated from each other by dielectric isolation regions 14. A gate 20 is formed directly over and in contact with the p-type regions 16 and the n-type regions 18. A top surface of the dielectric isolation regions 14 remains exposed. The p-type regions 16 and the n-type regions 18 can also be referred to as active device regions. The p-type region 16 can be referred to as a p-type field effect transistor (PFET) and the n-type region 18 can be referred to as an n-type FET (NFET).

In one or more embodiments, the substrate 10 can be a semiconductor or an insulator with an active surface semiconductor layer. The substrate 10 can be crystalline. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

Regarding various dielectrics or dielectric layers (such as the dielectric layer 12) discussed herein, the dielectrics can include, but are not limited to, SiO₂, SiN, SiOCN, SiOC, SiBCN, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

FIG. 2 is a cross-sectional view of FIG. 1, where middle-of-line (MOL) and back-end-of-line (BEOL) layers are formed over the device layer, in accordance with an embodiment of the present invention.

In various example embodiments, middle-of-line (MOL) 24, 26 and back-end-of-line (BEOL) layers 28 are formed over the device layer and within a first inter-layer dielectric (ILD) 22. This is referred to as the frontside BEOL.

The first ILD 22 can be any suitable material, such as, for example, porous silicates, carbon doped oxides, silicon dioxides, silicon nitrides, silicon oxynitrides, or other dielectric materials. Any known manner of forming the first ILD 22 can be utilized. The first ILD 22 can be formed using, for example, CVD, PECVD, ALD, flowable CVD, spin-on dielectrics, or PVD.

The manufacturing of leading-edge logic chips can be subdivided in three separate blocks: the front-end-of-line (FEOL), the middle-of-line (MOL) and the back-end-of-line (BEOL).

The FEOL covers the processing of the active parts of the chips, that is, the transistors that reside on the bottom of the chip. The transistor serves as an electrical switch and uses three electrodes for its operation: a gate, a source, and a drain. Electrical current in the conduction channel between source and drain can be switched between “on” and “off”, an operation that is controlled by the gate voltage.

The BEOL, the final stage of processing, refers to the interconnects that reside in the top part of the chip. Interconnects are complex wiring schemes that distribute clock and other signals, provide power and ground and transfer electrical signals from one transistor to another.

The BEOL is organized in different metal layers, local (Mx), intermediate, semi-global and global wires. The total number of layers can be as many as 15, while the usual number of Mx layers ranges between 3 and 6. Each of these layers contains (unidirectional) metal lines, organized in regular tracks, and dielectric materials. They are interconnected vertically by means of via structures that are filled with metal.

The FEOL and the BEOL are tied together by the MOL. The MOL is usually made up of tiny metal structures that serve as contacts to the transistor's source, drain, and gate. These structures connect to the local interconnect layers of the BEOL. While cell size is scaling, the number of pins to connect to remains roughly the same, meaning that access to them is more challenging.

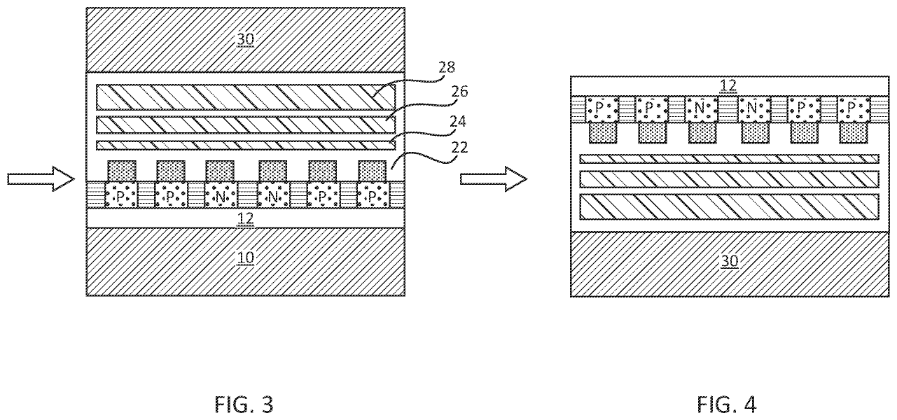

FIG. 3 is a cross-sectional view of FIG. 2, where a second substrate is formed over the MOL and BEOL layers, in accordance with an embodiment of the present invention.

In various example embodiments, a second substrate 30 is formed over the MOL layers 24, 26 and BEOL layers 28. Forming a second substrate is usually done by bonding a second substrate to the top of the existing wafer.

FIG. 4 is a cross-sectional view of FIG. 3, where the structure is flipped and the first substrate is selectively removed, in accordance with an embodiment of the present invention.

In various example embodiments, the structure is flipped and the first substrate 10 is selectively removed. Thus, the dielectric layer 12 becomes the top layer.

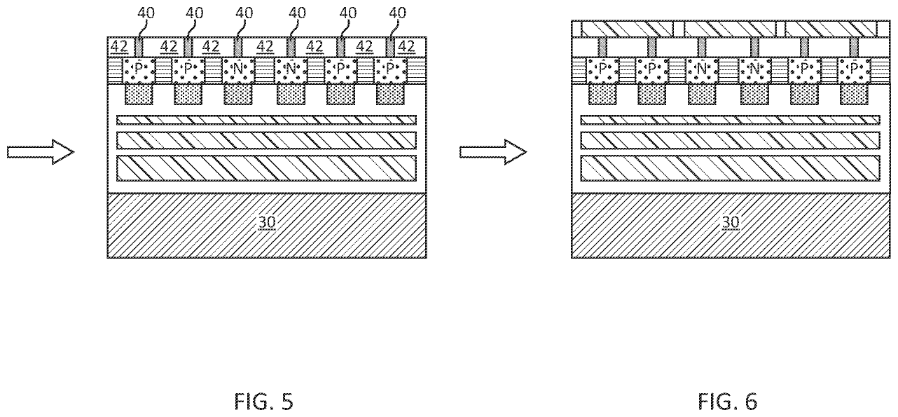

FIG. 5 is a cross-sectional view of FIG. 4, where vias are formed to the device layer, in accordance with an embodiment of the present invention.

In various example embodiments, a second dielectric layer 42 is deposited and vias 40 are formed to the device layer. The vias 40 directly contact the top surfaces of the p-type regions 16 and the n-type regions 18. The vias 40 are thus vertically aligned with the p-type regions 16 and the n-type regions 18. The vias 40 are vertically offset from the dielectric isolation regions 14.

FIG. 6 is a cross-sectional view of FIG. 5, where a backside power delivery level is formed over the vias, in accordance with an embodiment of the present invention.

In various example embodiments, a backside power delivery level 50 is formed over the vias 40. The backside power delivery level 50 directly contacts the vias 40.

A power delivery network (such as backside power delivery level 50) is designed to provide power supply and reference voltage (i.e., V_{DD} and V_{SS}) to the active devices on the die most efficiently. Traditionally, it is realized as a network of low-resistive metal wires fabricated through BEOL processing on the frontside of the wafer. The power delivery network shares this space with the signal network, i.e., the interconnects that are designed to transport the signal.

To deliver power from the package to the transistors, electrons traverse all layers of the BEOL stack through metal wires and vias that get increasingly narrow (thus, more resistive) when approaching the transistors. On their way, they lose energy, resulting in a power delivery or IR drop when bringing the power down. When arriving closer to the transistor, that is, at the standard cell level, the electrons end up in V_{DD} and V_{SS} power and ground rails organized in the Mᵢₙₜ layer of the BEOL. These rails take up space at the boundary and between each standard cell.

However, with each new technology generation, this traditional BEOL architecture struggles to keep pace with the transistor scaling path. Today, the “power interconnects” increasingly compete for space in the complex BEOL network and account for at least 20 percent of the routing resources. Also, the power and ground rails take up a considerably large area at the standard cell level, limiting further standard cell height scaling. At the system level, the power density and IR drop increase dramatically, challenging designers to maintain the 10 percent margin that is allowed for the power loss between the voltage regulator and the transistors.

The backside power delivery level (or network) 50 promises to address such issues. The idea is to decouple the power delivery network from the signal network by moving the entire power distribution network to the backside of the silicon wafer. From there, it enables direct power delivery to the standard cells through wider, less resistive metal lines, without electrons needing to travel through the complex BEOL stack. This approach promises to benefit the IR drop, improve the power delivery performance, reduce routing congestion in the BEOL, and when properly designed, allow for further standard cell height scaling.

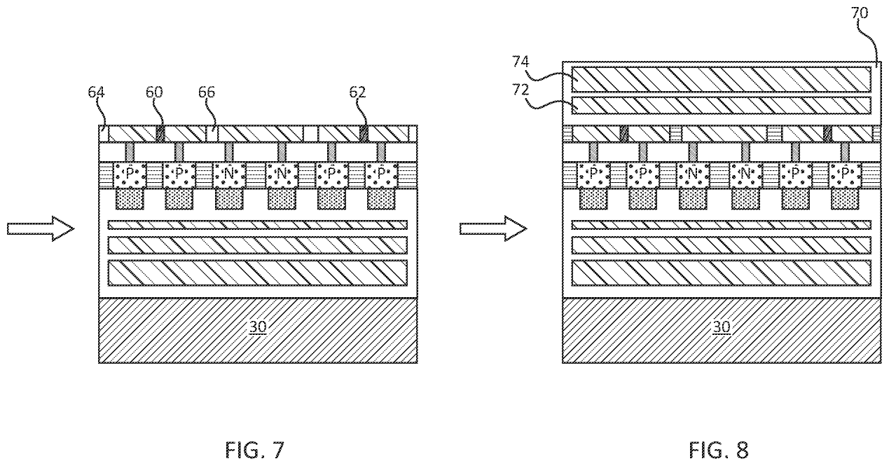

FIG. 7 is a cross-sectional view of FIG. 6, where narrow rail cuts are formed, in accordance with an embodiment of the present invention.

In various example embodiments, narrow rail cuts are formed within the backside power delivery level 50. FIG. 7 depicts wide rails 64, 66 and narrow rails 60, 62. A “wide rail” has a width of 120 nm to 250 nm, whereas a “narrow rail” has a width of 50 nm to 120 nm. The wide rails can be referred to as wide rail regions and the narrow rails can be referred to as narrow rail regions.

The narrow rails 60, 62 are vertically offset from the p-type regions 16 and the n-type regions 18. It is noted that the wide rails 64, 66 are also vertically offset from the p-type regions 16 and the n-type regions 18. The narrow rail 60 is parallel to the narrow rail 62. The wide rail 64 is horizontally aligned with both narrow rails 60, 62. As noted above, the p-type region 16 can be referred to as a p-type field effect transistor (PFET) and the n-type region 18 can be referred to as an n-type FET (NFET).

FIG. 8 is a cross-sectional view of FIG. 7, where additional backside BEOL is formed over the narrow rail cuts, in accordance with an embodiment of the present invention.

In various example embodiments, additional backside BEOL is formed over the narrow rail cuts. In particular, a second ILD 70 is formed over the narrow rails 60, 62, and BEOL 72, 74 is formed within the second ILD 70. Thus, structure 80 depicts the narrow rails 60, 62 and the wide rails 64, 66 confined between BEOL 26, 28 and BEOL 72, 74. This is referred to as the backside BEOL.

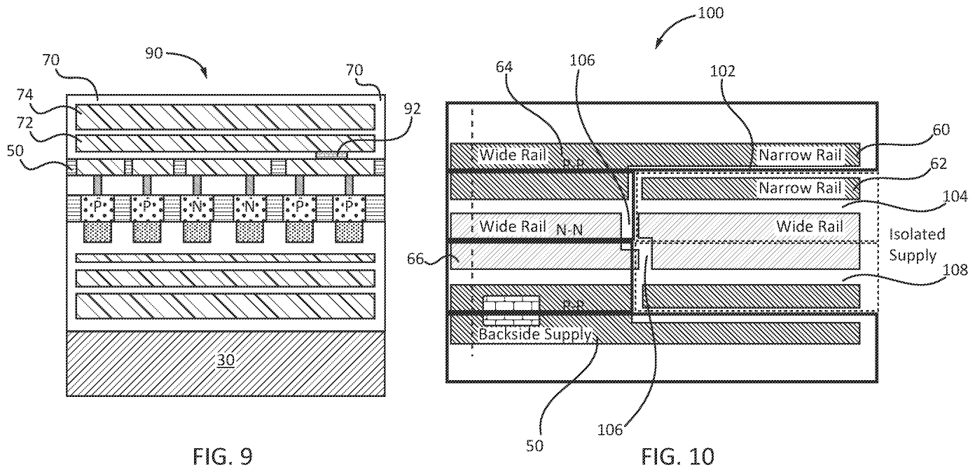

FIG. 9 is a cross-sectional view of FIG. 6, where a via is connected to the primary rail region, in accordance with an embodiment of the present invention.

In various example embodiments, in structure 90, a via 92 is connected to the primary rail region. A supply voltage connection for each narrow rail 60, 62 is provided by the via 92 connected to the primary rail region. In other words, the via 92 connects two backside wiring levels (power or ground).

FIG. 10 is a top view of FIG. 8, where the wide rails and the narrow rails are illustrated, in accordance with an embodiment of the present invention.

In various example embodiments, the top view 100 illustrates the wide rails 64, 66 and the narrow rails 60, 62. The “wide rail” has a width of 120 nm to 250 nm, whereas a “narrow rail” has a width of 50 nm to 120 nm. The narrow rails 60, 62 are separated by a distance or gap 102 of about 10 nm to 20 nm.

The wide rail 64 and the narrow rails 60, 62 are contiguous. Stated differently, wide rail 64 and the narrow rails 60, 62 share a common border or are touching. A width of the narrow rails 60, 62 is equal to a width of the wide rail 64. The rails are located at N-N and/or P-P boundaries. In one embodiment, the adjacent narrow rails 60, 62 have a same voltage.

The narrow rails 60, 62 are separated by the wide rail 66 by a gap 104. The wide rail 66 is separated by the backside supply backside power delivery level 50 by a gap 108. The wide rail 66 has a cut 106. The cut 106 can be substantially Z-shaped. The cut 106 is a substantially vertical cut. Adjacent narrow rails 60, 62 are isolated by a long lateral cut.

Stated differently, the top view 100 depicts a primary rail and two secondary rails, where the primary rail has a width equal to a width of the two secondary rails. The two secondary rails are separated from each other by a gap. The primary rail can be referred to as a wide rail and the secondary rails can be referred to as narrow rails.

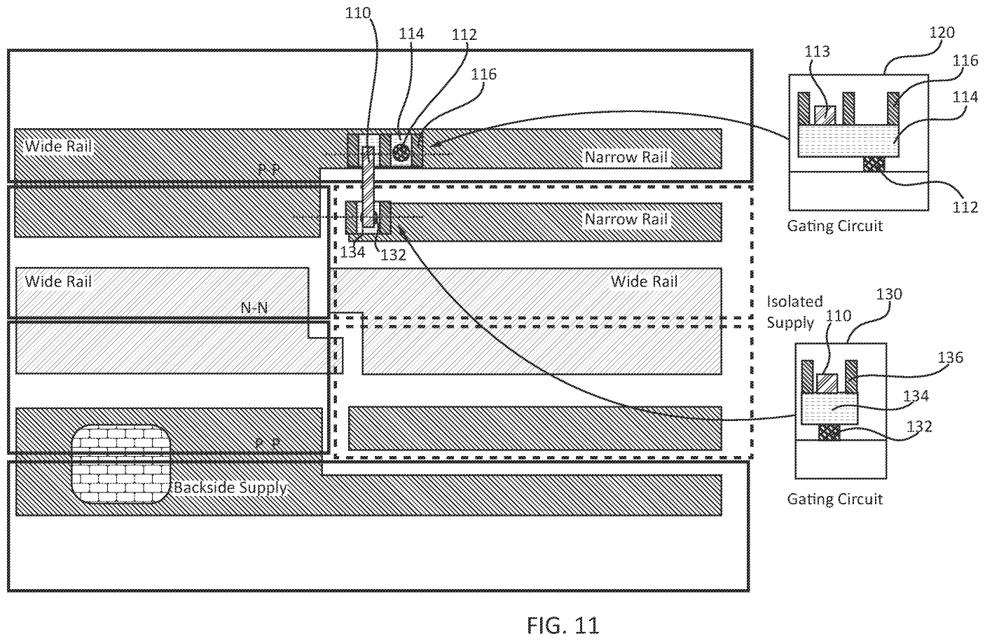

FIG. 11 is a top view of FIG. 8, where the wide rails and the narrow rails are illustrated, as well as an MOL contact connecting the narrow rails, and gating circuits used to supply power between the narrow rails, in accordance with an embodiment of the present invention.

In various example embodiments, a gating circuit 120 is used to supply power to the narrow rail 60 and a gating circuit 130 is used to supply power to the narrow rail 62.

The gating circuit 120 includes an MOL contact 110, a source/drain (S/D) region contact 112, a semiconductor region 114, and an isolation gate 116. The MOL contact 110 connects adjacent transistor S/D regions. The S/D region contact 112 is a contact from the S/D region to the backside power or the ground wiring.

The gating circuit 130 includes the MOL contact 110, a S/D region contact 132, a semiconductor region 134, and an isolation gate 136. The MOL contact 110 electrically connects the first gating circuit 120 to the second gating circuit 130. The MOL contact 110 electrically connects narrow rail 60 to narrow rail 62. Stated differently, adjacent narrow rails 60, 62 are connected by the MOL contact 110 to provide supply voltage from one narrow rail to the adjacent narrow rail.

In an alternative embodiment, two supply rails are isolated with a non-rectangular cut region, and/or two supply rails are isolated with a diagonal cut region, and/or two supply rails are connected by transistor which is above cut region, and an isolated supply rail is connected by transistors at each end which are above cut regions.

In conclusion, the exemplary embodiments of the present invention present structures and methods for constructing a split backside power rail for isolated supply. The power rail at a given level is split into multiple parallel power rails, referred to as narrow rails or narrow rail regions. Gating circuits are also used to supply power to the narrow rails. Moreover, the chip includes backside supply rails having a primary wide rail region and adjacent narrow rail regions with one of the narrow rail regions being isolated from the wide rail region. The wide rail region and one narrow rail region are contiguous. The width of the two narrow rail regions is equal to a width of the wide rail region. The rails are located at N-N and/or P-P boundaries. In one embodiments, adjacent narrow rail regions are connected by a transistor to provide supply from one narrow rail region to the adjacent narrow rail region. In another embodiment, the adjacent narrow rail regions have a same voltage. In other embodiments, the supply voltage connection for the narrow rail region is provided by a via to connect to the wide rail region.

Further, the exemplary method includes forming active devices, forming frontside BEOL, flipping the wafer, forming backside vias, forming a first metal layer with cuts to isolate the narrow line regions from the wide line regions, forming an additional backside BEOL, forming interconnects, and constructing the backside BEOL levels.

Regarding FIGS. 1-11, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process. Ruthenium metal is generally etched using O₂ with Ar for the physical component and CH₄ as a dilution gas to reduce the polymerization. Other dry etchant gasses can include, chlorine base gases (e.g., Cl₂, BCl₃), Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing a split backside power rail for isolated supply (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a plurality of backside supply rails;
a primary wide rail region; and
a plurality of adjacent narrow rail regions, wherein at least one of the adjacent narrow rail regions is isolated from the primary wide rail region.

2. The semiconductor structure of claim 1, wherein the primary wide rail region and the at least one of the adjacent narrow rail regions are contiguous.

3. The semiconductor structure of claim 1, wherein a width of two adjacent narrow rail regions is equal to a width of the primary wide rail region.

4. The semiconductor structure of claim 1, wherein the wide rail region and the plurality of adjacent narrow rail regions are at N-N and P-P boundaries.

5. The semiconductor structure of claim 1, wherein the plurality of adjacent narrow rail regions are connected by a transistor to provide supply power from one narrow rail region to an adjacent other narrow rail region.

6. The semiconductor structure of claim 1, wherein the plurality of adjacent narrow rail regions have a same voltage.

7. The semiconductor structure of claim 1, wherein a supply voltage connection for each narrow rail region is provided by a via connected to the primary wide rail region.

8. The semiconductor structure of claim 1, wherein the primary wide rail region is isolated from an adjacent narrow rail region of the plurality of adjacent narrow rail regions by a cut.

9. The semiconductor structure of claim 1, wherein the plurality of adjacent narrow rail regions are isolated by a lateral cut.

10. The semiconductor structure of claim 1, wherein the primary wide rail region has a width between 120 nm and 250 nm.

11. The semiconductor structure of claim 1, wherein each narrow rail region of the plurality of adjacent narrow rail regions has a width between 50 nm and 120 nm.

12. The semiconductor structure of claim 11, wherein a gap region between the plurality of adjacent narrow rail regions has a width between 10 nm and 20 nm.

13. A semiconductor structure comprising:
a primary rail;
a first secondary rail and a second secondary rail, wherein the second secondary rail is isolated from the primary rail; and
a transistor connecting the first secondary rail to the second secondary rail to supply power therebetween.

14. The semiconductor structure of claim 13, wherein the primary rail is contiguous only with the second secondary rail.

15. The semiconductor structure of claim 13, wherein a width of the first and second secondary rails is equal to a width of the primary rail.

16. The semiconductor structure of claim 13, wherein a supply voltage connection for the first and second secondary rails is provided by a via connected to the primary rail.

17. The semiconductor structure of claim 13, wherein the first secondary rail is isolated from the second secondary rail by a lateral cut.

18. The semiconductor structure of claim 13, wherein the primary rail has a width between 120 nm and 250 nm, and each of the first and second secondary rails has a width between 50 nm and 120 nm.

19. A method for constructing a semiconductor structure, the method comprising:
constructing a plurality of backside supply rails;
constructing a primary wide rail region; and
constructing a plurality of adjacent narrow rail regions, wherein at least one of the adjacent narrow rail regions is isolated from the primary wide rail region and wherein the primary rail is contiguous only with the second secondary rail.

20. The method of claim 19, wherein the primary rail has a width between 120 nm and 250 nm, and each of the first and second secondary rails has a width between 50 nm and 120 nm.
